(19) United States
(12) Patent Application Publication
(10) Pub. No.: US 2010/0297802 A1
(43) Pub. Date: Nov. 25, 2010

(54) SOLAR CELL ASSEMBLIES AND METHOD OF MANUFACTURING SOLAR CELL ASSEMBLIES

(75) Inventors: Christian Becker, Mainz (DE); Hans-Juergen Eickelmann, Nieder-Hilbersheim (DE); Michael Haag, Rodenbach (DE); Rainer Klaus Krause, Main-Kostheim (DE); Markus Schmidt, Seibersbach (DE)

Correspondence Address: Lieberman & Brandsdorfer, LLC, 802 Still Creek Lane, Gaithersburg, MD, 20878, US

(73) Assignee: INTERNATIONAL BUSINESS MACHINES CORPORATION, Armonk, NY (US)

(21) Appl. No.: 12/849,207

(22) Filed: Aug. 3, 2010

Related U.S. Application Data
(62) Division of application No. 12/189,960, filed on Aug. 12, 2008.

(51) Int. Cl. H01L 31/18

(52) U.S. Cl. 438/67; 257/E31.11

(57) ABSTRACT

Solar cell assemblies and method of making solar cell assemblies. The method, including: fabricating solar cell chips on solar cell wafers; dicing the solar cell wafers into individual solar cell chips; packaging the individual solar cell chips in molded plastic packages to form solar cell chip packages; and mounting on and electrically connecting one or more of the solar cell chip packages to a printed circuit board. The assemblies including a printed circuit board; one or more solar cell chip packages mounted on and electrically connected to the printed circuit board, each of said one or more solar chip packages comprising a solar cell chip and a lead frame encapsulated in a molded plastic body, top surfaces the solar cell chips exposed in top surfaces of the molded plastic bodies.

### CROSS REFERENCE TO RELATED APPLICATION(S)

This application is a division of application Ser. No. 12/189,960, filed Aug. 12, 2008, now pending, which is hereby incorporated herein by reference.

### FIELD OF THE INVENTION

The present invention relates to the field of solar cells; more specifically, it relates to a method of fabricating a solar cell assembly.

### BACKGROUND OF THE INVENTION

Solar cells or solar concentrators are semiconductor devices capable of generating electricity using the photovoltaic effect. The relatively high cost of fabricating solar cells and inability to easily configure voltage and current output as well as the difficulty in repairing solar cell arrays has seriously limited the widespread use of solar cells. Accordingly, there exists a need in the art to mitigate the deficiencies and limitations described hereinabove.

### SUMMARY OF THE INVENTION

A first aspect of the present invention is a method, comprising: (a) fabricating solar cell chips on solar cell wafers; (b) dicing the solar cell wafers into individual solar cell chips; (c) packaging the individual solar cell chips in molded plastic packages to form solar cell chip packages; and (d) mounting on and electrically connecting one or more of the solar cell chip packages to a printed circuit board.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIG. 1 is a cross-sectional drawings illustrating an exemplary solar cell chip according to embodiments of the present invention through line 1-1 of FIGS. 2 and 3;

FIG. 2 is a top view of the solar cell of FIG. 1;

FIG. 3 is a bottom view of the solar cell of FIG. 1;

FIG. 4 is a top view of the solar cell chip of FIGS. 1, 2 and 3 in a plastic package;

FIG. 5A is a cross-section of the solar cell chip and package of FIG. 4 through line 5A-5A;

FIG. 5B is a cross-section of a first alternative plastic package containing the solar cell chip of FIGS. 1, 2 and 3;

FIG. 5C is a cross-section of a second alternative plastic package containing the solar cell chip of FIGS. 1, 2 and 3;

FIG. 6A is a top view of an exemplary printed circuit board for a solar cell chip assembly configured for the solar cell/chip package of FIGS. 4 and 5A according to embodiments of the present invention;

FIG. 6B is a bottom view of the exemplary printed circuit board of FIG. 6A;

FIG. 7 is a cross-section view the exemplary printed circuit board of FIGS. 6A and 6B through line 7-7 of FIGS. 6A and 6B;

FIG. 8 is a cross-section view the exemplary printed circuit board of FIGS. 6A/6B and 7 having the packaged solar cell of FIGS. 4 and 5A attached;

FIG. 9, is a top view of an exemplary printed circuit board for a multiple solar cell chip packages according to embodiments of the present invention;

FIG. 10A is a bottom view of the exemplary printed circuit board of FIG. 9 for parallel interconnection of solar cell chip packages according to embodiments of the present invention;

FIG. 10B is a bottom view of the exemplary printed circuit board of FIG. 9 for serial interconnection of solar cell chip packages according to embodiments of the present invention;

FIG. 11 is a cross-section view of an exemplary printed circuit board for a solar cell chip assembly configured for the solar cell/chip package of FIG. 5B according to embodiments of the present invention;

FIG. 12 is a cross-section view of an exemplary printed circuit board for a solar cell chip assembly configured for the solar cell/chip package of FIG. 5C according to embodiments of the present invention;

FIG. 13A illustrates attaching a contact frame of a solar cell chip to a lead of a package using wire bonding and FIG. 13B illustrates attaching a contact frame of a solar cell chip to a lead of a package using lead bonding;

FIG. 14 is a cross-section view of an exemplary printed circuit board for a cooled solar cell chip assembly configured for the solar cell/chip package of FIG. 5B according to embodiments of the present invention;

FIG. 15 is a top view of multi-solar-chip assembly according to embodiments of the present invention; and

FIG. 16 is a flowchart illustrating the major steps required to practice the embodiments of the present invention.

### DETAILED DESCRIPTION OF THE INVENTION

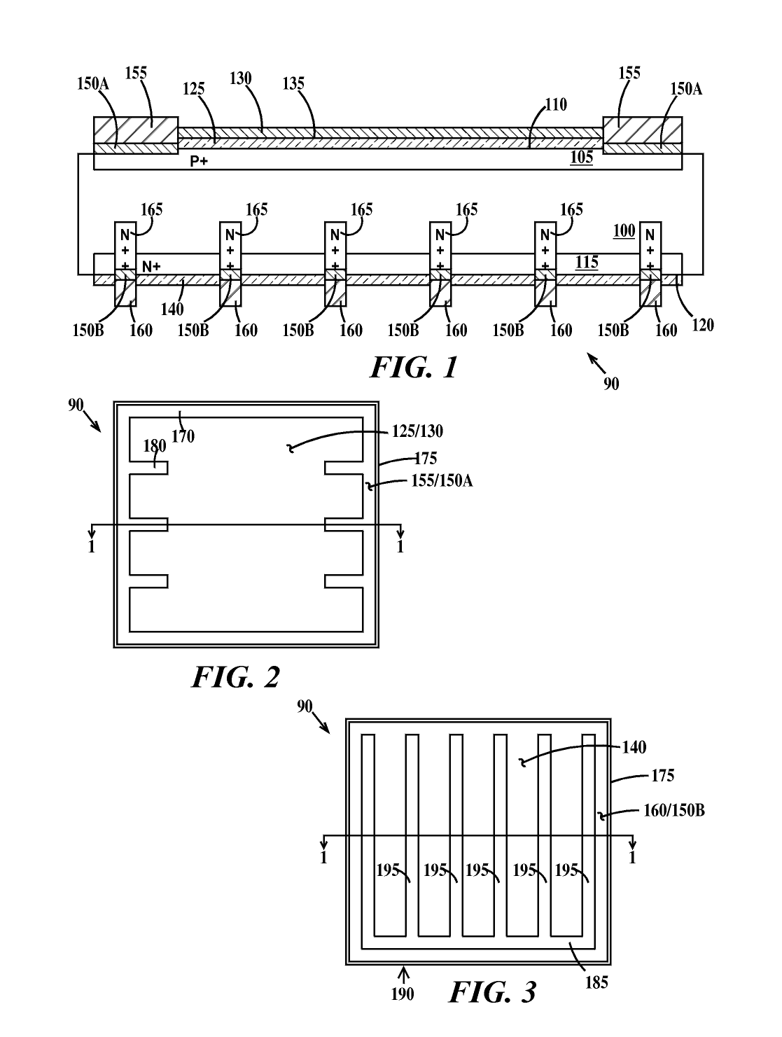

FIG. 1 is a cross-sectional drawing illustrating an exemplary solar cell chip according to embodiments of the present invention through line 1-1 of FIGS. 2 and 3. In FIG. 1, a solar cell chip 90 includes a silicon substrate 100 having a P-doped region 105 abutting a top surface 110 of the substrate and an N-doped region 115 abutting a bottom surface 120 of the substrate. A top passivation layer 125 is formed on top surface 110 of substrate 100 and an antireflective coating 130 formed on a top surface 135 of top passivation layer 125. A bottom passivation layer 140 is formed on bottom surface 120 of substrate 100. A metal silicide contact 150A is formed through top passivation layer 125 and antireflective coating 130 to electrically contact P-doped region 105. A metal silicide contact 150B formed through bottom passivation layer 140 electrically contact P-doped region 115. A metal contact frame 155 electrically contacts metal silicide contact 150A and a metal bus bar 160 electrically contacts metal silicide contact 150B. Solar cell chip 90 includes optional N-doped emitters 165 under metal silicide contact 150 extending through and past N-doped region 115 into substrate 100.

FIG. 2 is a top view of the solar cell of FIG. 1. In FIG. 2, it can be seen that contact frame 155 includes a peripheral region 170 adjacent to a perimeter 175 of solar cell chip 90 and extensions regions 180 extending out from peripheral region 170 toward the interior of the chip. Metal silicide contact 150A extends under contact frame 155. In FIGS. 1 and 2, contract frame 155 is illustrated as coextensive with silicide layer 150A. Alternatively, contact frame 155 may overlap silicide layer 150A.

FIG. 3 is a bottom view of the solar cell of FIG. 1. In FIG. 3, bus bar 160 includes a first region 185 parallel to an edge 190 of solar cell chip 90 and finger regions 195 extending across the chip toward a side opposite side 190. Metal silicide contact 150B extends under bus bar 160. In FIGS. 1 and 3, bus bar 160 is illustrated as coextensive with silicide layer 150B. Alternatively, bus bar 160 may overlap silicide layer 150B.

Solar cell chip 90 is exemplary and is illustrated so interconnections between solar cell chips and the next level of packaging can be illustrated. The invention should be understood as not being limited to any particular solar cell chip and that other solar cell chips as known in the art may be substituted.

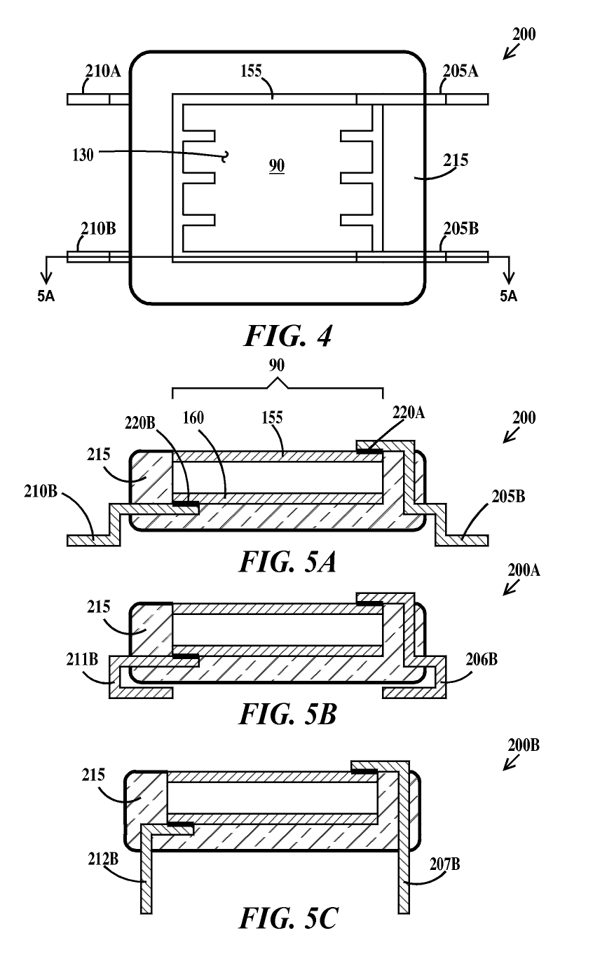

FIG. 4 is a top view of the solar cell chip of FIGS. 1, 2 and 3 in a plastic package. In FIG. 4, solar cell chip 90 is packaged in a molded plastic (or other polymeric material) package to form a solar cell chip package 200. Package 200 includes first leads 205A and 205B connected to contact frame 155 and second leads 210A and 210B connected to bus bar 160 (see FIG. 5A) encapsulated in a plastic body 215. Contact frame 155 and antireflective coating 130 are not covered by body 215 but exposed in a top surface of the body.

FIG. 5A is a cross-section of the solar cell chip and package of FIG. 4 through line 5A-5A. In FIG. 5A, lead 205B (and 205A, see FIG. 4) is electrically and physically connected to contact frame 155 by solder interconnects 220A and lead 210B (and 210A, see FIG. 4) are electrically and physically connected to bus bar 160 by solder interconnects 220B. Other lead connection methods include wire bonding (see FIG. 15A) and gold or aluminum bump bonding (see FIG. 15B). The processes used to connect leads 205A and 205B to contact frame 155 and leads 210A and 210B to bus bar 160 may be independently selected from the group consisting of soldering, wire bonding and gold bump bonding (see FIGS. 13A and 13B and discussion infra). Package 200 is a surface mount package and leads 205A, 205B, 210A and 210B extend away from body 215.

FIG. 5B is a cross-section of a first alternative plastic package containing the solar cell chip of FIGS. 1, 2 and 3. In FIG. 5B, a package 200A is similar package 200 of FIG. 5A, except leads 206A, 206B, 211A and 211B which respectively replace leads 205A, 205B, 210A and 210B of FIG. 5A, extend under body 215. Package 200A is often referred to a “J” lead package. Package 200A may be surface mounted or socket mounted.

FIG. 5C is a cross-section of a second alternative plastic package containing the solar cell chip of FIGS. 1, 2 and 3. In FIG. 5C, a package 200B is similar package 200 of FIG. 5A, except leads 207A, 207B, 212A and 212B which respectively replace leads 205A, 205B, 210A and 210B of FIG. 5A, are pins. Package 200A may be through via soldered (see FIG. 12) or socket mounted.

By using integrated circuit industry standard fabrication processes and tools and fabricating solar cell chips in integrated circuit fabrication facilities costs can be reduced. By using integrated circuit industry standard packages and packaging solar cell chips in integrated circuit package facilities costs can be reduced. Interference of solar cell fabrication with integrated circuit chip fabrication and packaging can be reduced to a minimum by assigning low priority to solar cell fabrication in integrated circuit facilities and using otherwise tool idle time.

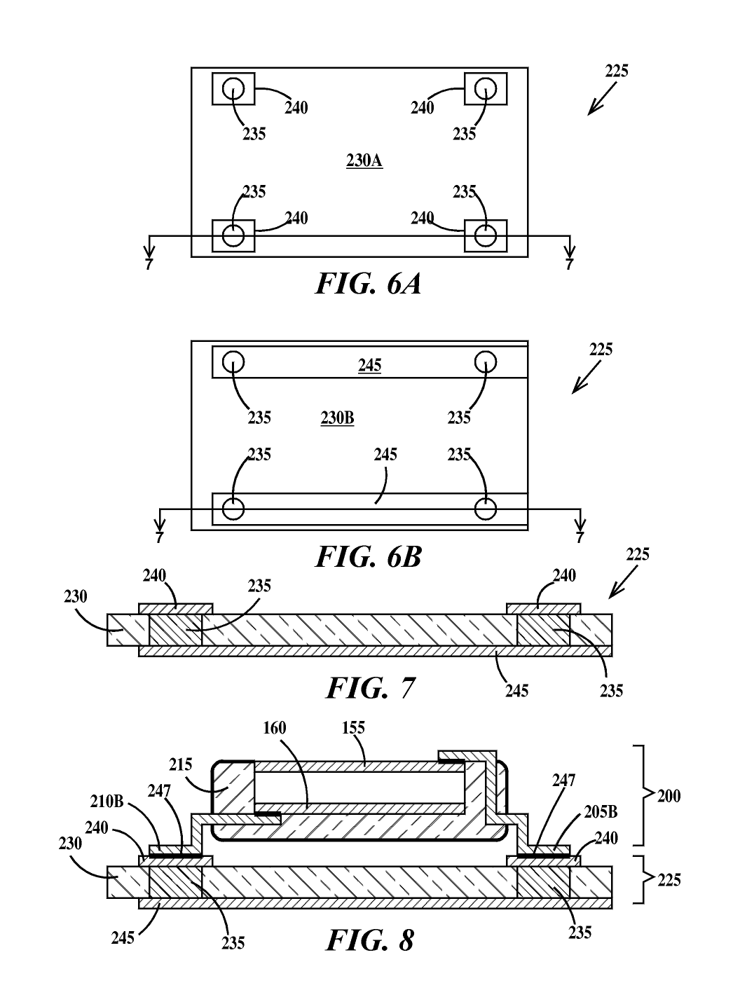

FIG. 6A is a top view, FIG. 6B is a bottom view and FIG. 7 is a cross-section view rough line 7-7 of FIGS. 6A and 6B of an exemplary printed circuit board for a solar cell chip assembly configured for the solar cell/chip package of FIGS. 4 and 5A according to embodiments of the present invention. A printed circuit board (PCB) 225 includes electrically conductive through vias 235 connected to metal pads 240 on top surface 230A of PCB 225 and metal lands 245 on bottom surface 230B of PCB 225. Lands 245 may act as edge connectors to connect package 200 the outside world. Through vias 235 may be plated through vias. Alternatively, for PCB 225 and PCB 225A, 225B described infra, lands 245 may also be formed on the top surface of the PCB eliminating the need for through vias.

FIG. 8 is a cross-section view of the exemplary printed circuit board of FIGS. 6A/6B and 7 having the packaged solar cell of FIGS. 4 and 5A attached. In FIG. 8 leads 205B and 210B (and 205A and 210A, see FIG. 6A) and are electrically and physically connected to pads 240 by solder joints 247.

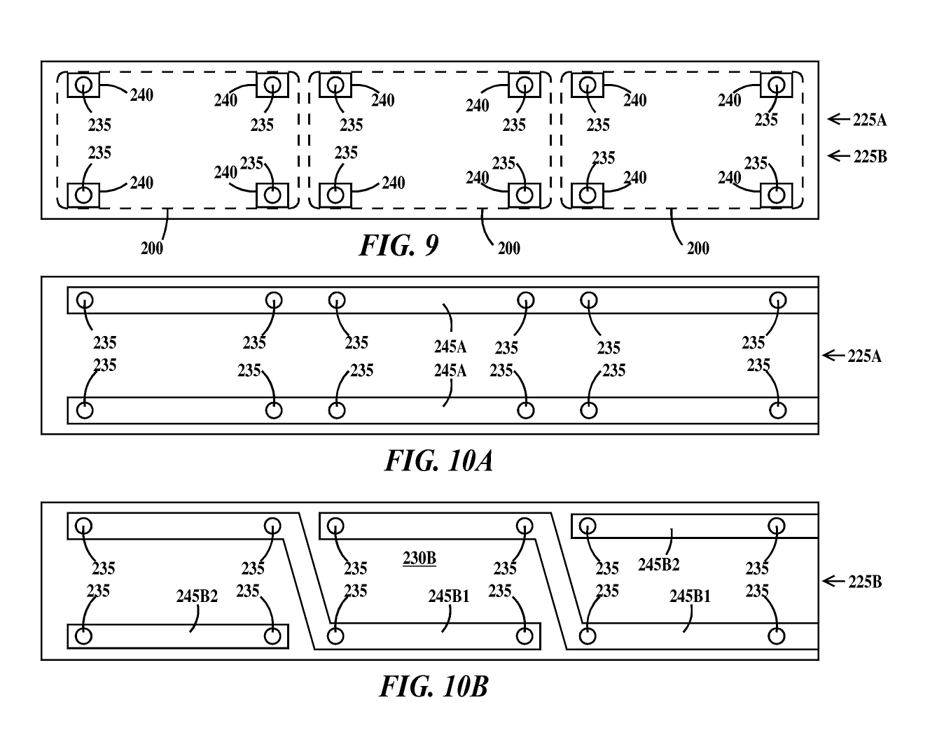

FIG. 9 is a top view, FIG. 10A is a bottom view for parallel interconnection of solar cell chip packages and FIG. 10B is a bottom view for serial interconnection of solar cell chip packages of exemplary printed circuit boards for a multiple solar cell chip/package assemblies according to embodiments of the present invention. In FIG. 9, a top surface of PCB 225A or 225B has sufficient pads 240 and through vias 235 for three packages 200 (dashed lines). In FIG. 10A, a bottom surface of PCB 225A has a pair of lands 245A each interconnecting all the through vias in different rows of through vias 235. PCB 225A thus has a voltage output of one solar cell chip but the current capacity of three solar cell chips. In FIG. 10B, a bottom surface of PCB 225B has a pair of lands 245B1 interconnecting pairs of through vias in different rows of through vias and a pair of lands 245B2 interconnecting a pair of vias in respective same rows of through vias 235. PCB 225B thus has a voltage output of three solar cell chips but the current capacity of one solar cell chip.

It should be understood that PCBs may be fabricated having N by M arrays of solar cell chip packages (N and M being integers such that N+M is at least 3 and neither N or M are 0) and wired in parallel and series combinations. At least three solar cell chip packages are required for parallel and series combinations. It should also be understood, that because each solar cell chip package is connected individually to the PCB, individual solar cell chip packages may be removed and replaced.

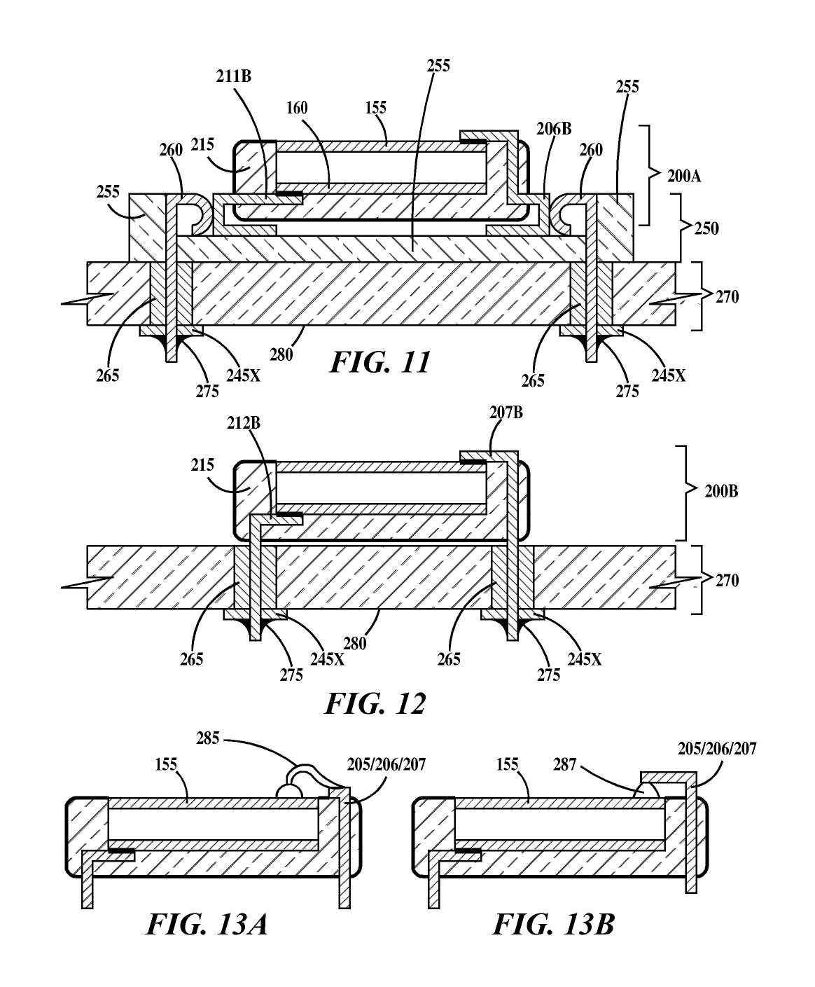

FIG. 11 is a cross-section view of an exemplary printed circuit board for a solar cell chip assembly configured for the solar cell/chip package of FIG. 5B according to embodiments of the present invention. In FIG. 11, a solar cell chip package 200A is removeably held in a respective socket 250. While one cell chip package 200A/socket 250 pairs is illustrated in FIG. 11, there may be two or more solar cell chip package 200A/socket 250 pairs. Socket 250 includes a plastic body 255 and pin clips 260. Pin clips 260 not only act as spring clip connections for leads 206B and 211B (and 206A and 211A, not shown) but also pass through vias 265 of PCB 270 and are soldered (275) to lands 245X on the bottom surface 280 of the PCB. Lands 245X wire sockets 250 and therefore solar cell chip packages 200A in any number of serial and parallel combinations. Because solar cell chip packages 200A are held in sockets 250, it is very easy to replace any particular package if it is found to be defective.

FIG. 12 is a cross-section view of an exemplary printed circuit board for a solar cell chip assembly configured for the solar cell/chip package of FIG. 5C according to embodiments of the present invention. In FIG. 12, a solar cell chip package 200B is soldered (275) to lands 245X on the bottom surface 280 of PCB 270. While one cell chip package 200B is illustrated in FIG. 11, there may be two or more solar cell chip packages 200B. Lands 245X are configured to wire solar cell chip packages 200B in any number of serial and parallel combinations. Because solar cell chip packages 200B are soldered 250, it is easy to replace any particular package if it is found to be defective.

FIG. 13A illustrates attaching a contact frame of a solar cell chip to a lead of a package using wire bonding and FIG. 13B illustrates attaching a contact frame of a solar cell chip to a lead of a package using lead bonding. Wire bonding and lead bonding may be applied to any of solar cell chip packages 200, 200A and 200B discussed supra. In FIG. 13A, a lead 205/206/207 is electrically connected to contact frame 155 by a wire bond 285. In wire bonding, a ball formed on a first end of a wire by melting one end of a gold or aluminum wire and ultrasonically bonding the ball to frame 155 and then ultrasonically forming a wedge bond at a second end of the wire to lead 205/206/207. Alternatively, wedge bonds may be formed at both ends of the wire. In FIG. 13A, a lead 205/206/207 is electrically connected to contact frame 155 by a bump 290. In lead bonding, bump 287 (e.g., gold) is formed on lead 205/206/207 and contact frame 155 is ultrasonically bonded to the bump.

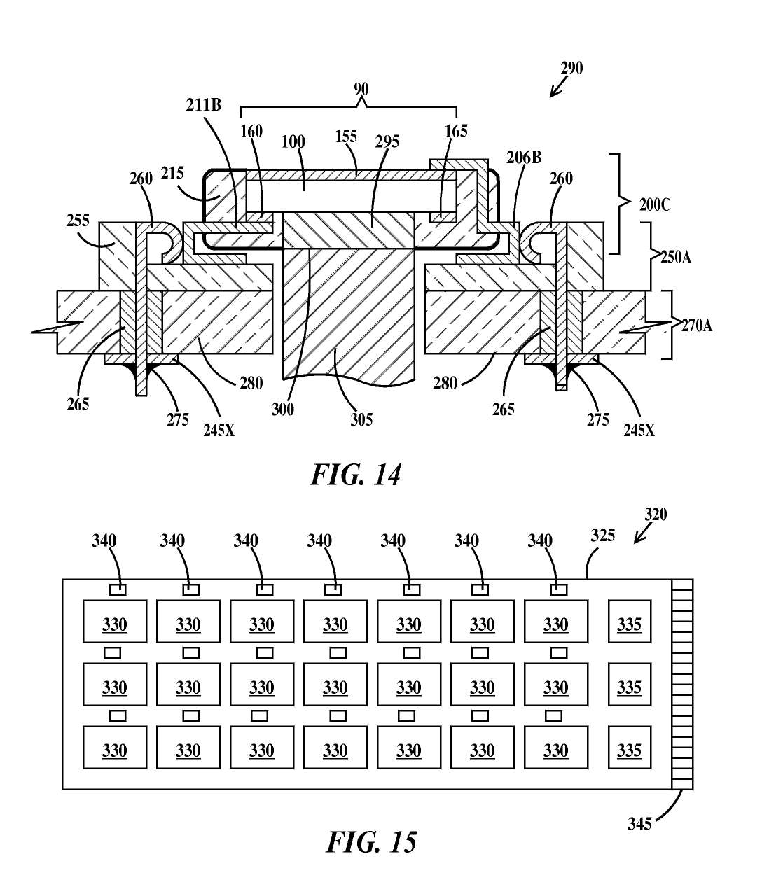

FIG. 14 is a cross-section view of an exemplary printed circuit board for a cooled solar cell chip assembly configured for the solar cell/chip package of FIG. 5B according to embodiments of the present invention. In FIG. 14, an assembly 290 includes a solar cell chip package 200C, a socket 250A and a PCB 270A. There may be multiple cell chip package 200C/socket 250A sets on PCB 270A. Solar cell chip package 220C is similar to solar cell chip package 200A of FIG. 11 except a thermally conductive heat spreader 295 is embedded in body 215 and is in contact with substrate 100 of solar cell chip 90. A surface 300 of heat spreader 295 is exposed in the bottom surface of solar cell chip package 200C and not covered by body 215. Socket 250A is similar to socket 250 of FIG. 11, except for an opening under heat spreader 295. PCB 270A is similar to PCB 270 of FIG. 11, except for an opening under heat spreader 295. The respective openings in socket 250A and PCB 270A allow a cooling device 305 to be inserted through sockets 250A and PCB 270A in order to contact surface 300 of heat spreader 295. Cooling device 305 may include channels for recirculating a gas or liquid coolant or may be a Peltier device. The heat spreader/cold finger concept may be applied to other embodiments of the present invention. For example, solar cell chip package 200 and PCB board of FIG. 8 and solar cell chip package 200B and PCB 270 of FIG. 12 may be configured for a heat spread and cooling device.

FIG. 15 is a top view of multi-solar-chip assembly according to embodiments of the present invention. In FIG. 15, an assembly 320 includes a PCB 325, an array of solar cell chip packages 330, optional control integrated circuits (ICs) 335 and optional devices 340 mounted to the PCB. PCB 325 is provided with an edge connection 345. Electrically conductive lands (not illustrated in FIG. 15) on the top surface, or bottom surface, or interior regions of PCB 325 or combinations thereof interconnect solar cell chip packages 330, ICs 335 and devices 340 to each other and edge connection 345. Solar cell packages 330 may be wired in combinations of parallel and series. Devices 340 may be selected from the group consisting of resisters, capacitors, inductors, diodes and transistors. Integrated circuit chips 335 may include voltage regulators or current regulators or both. Integrated circuit chips 335 may include logic circuits, memory circuits, switching circuits to change the wiring of solar cell chip packages 330 in order change the voltage output and/or current capacity of assembly 320. Solar cell chip packages 330 may consist of any of the solar cell chip package embodiments described supra, including those illustrated in FIGS. 8, 11, 12, 13A, 13B and 14.

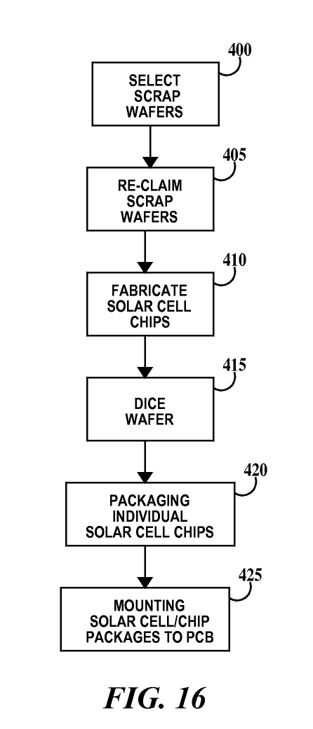

FIG. 16 is a flowchart illustrating the major steps required to practice the embodiments of the present invention. A wafer is a disc shaped silicon substrate. An integrated circuit chip is defined as a chip having at least one memory, logic or analog circuit comprised of at least one transistor (e.g., field effect transistor or bipolar transistor). In step 400, scrap wafers which include wafers on which one or fabrication steps used to make integrated circuit chips has been performed or monitor wafers used in monitoring semi-conductor processes in a integrated circuit manufacturing facility are selected. Scrap wafers include wafers which were misprocessed or which failed testing.

In step 405, the wafers are reclaimed by grinding top and/or bottom surfaces of the scrap wafers, chemical-mechanical polishing the top and/or bottom surfaces of the scrap wafers, chemically treating (including etching) the top and/or bottom surfaces of the scrap wafers or performing combinations thereof.

In step 410, multiple solar cell chips are fabricated using the reclaimed wafers. Fabrication may include processing the reclaimed wafers on one or more tools normally used to fabricate integrated circuit chips. Fabrication may include processing the reclaimed wafers on one or more tools used to fabricate solar cell chips. Fabrication may include processing the reclaimed wafers only on tools normally used to fabricate integrated circuit chips. Fabrication may include processing the reclaimed wafers only on tools used to fabricate solar cell chips. Testing of the solar cell chips while still in wafer form may be performed prior to step 415

In step 415, the wafers are diced (singulated) into individual solar cell chips. If testing was performed in step 410, only tested good solar cell chips proceed to step 420. The individual solar cell chips range in surface area from about 25 mm² to about 400 mm².

In step 420, individual solar cell chips are packaged in plastic packages. Packaging the solar cell chips includes, placing the solar cell chip on a lead frame, providing contact wiring between the solar cell chip and leads of the lead frame (e.g., by soldering, wire bonding, or bump bonding), and encapsulating the solar cell chip and lead frame in plastic or other polymeric material. Step 420 may include testing of the completed solar cell chip packages. It should be understood, that in encapsulating solar cell chips the light collecting surface of the solar cell chip is not covered by molding material.

In step 425, one or more solar cell chip packages are mounted on a printed circuit board. The mounting of the solar cell chips may be electrically connected in series to increase the voltage output of the completed assembly, in electrically connected in parallel to increase the current capacity of the completed assembly or electrically connected both in series and parallel. Mounting of the solar cell chip packages may be by soldering to pads on the PCB or by removeably inserting the solar cell chip packages into sockets that have been soldered to the PCB.

A solar cell chip is essentially a light collecting diode. In one example, solar cell chips according to embodiments of the present invention contain only a single light collecting diode. In one example, solar cell chips of the present invention may include two or more light collecting diodes electrically isolated from each other except for series or parallel connections. In one example, solar cell chips according to embodiments of the present invention consist only of combinations of light collecting diodes, wires, passivation layers and antireflective coatings. In one example, solar cell chips according to embodiments of the present invention consist of only combinations of light collecting diodes, wires, passivation layers, antireflective coatings, and electrical isolation structures.

Thus the embodiments of the present invention provide a solar cell assembly configurable for different voltage/current combinations and relatively easily repairable.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A method, comprising:
(a) fabricating solar cell chips on solar cell wafers;
(b) dicing said solar cell wafers into individual solar cell chips;
(c) packaging said individual solar cell chips in molded plastic packages to form solar cell chip packages; and
(d) mounting on and electrically connecting one or more of said solar cell chip package to a printed circuit board.

2. The method of claim 1, wherein each of said one or more solar cell chip packages is soldered to pads on a top surface of said printed circuit board.

3. The method of claim 1, further including:
between (c) and (d), soldering one or more sockets onto pads on said top surface of said printed circuit board; and
after said soldering said one or more sockets, inserting each of said one or more solar cell chip packages into a respective sockets of said one or more sockets.

4. The method of claim 1, wherein said solar chips have a contact frame on a top surface and a bus bar an opposite bottom surface, said top surface of said solar chips exposed in a top surface of said packages, a first set of leads of said packages soldered to said bus bar and a second set of leads of said package either soldered, wire bonded or bump bonded to said contact frames.

5. The method of claim 1, wherein when there are two or more integrated circuit chip packages mounted on said printed circuit board, electrically connecting said two or more solar cell chip packages in series, electrically connecting said two or more solar cell chip packages in parallel, or when there are three or more integrated circuit chip packages mounted on said printed circuit board electrically connecting said three or more solar cell chip packages in a series and parallel combination.

6. The method of claim 1, further including:
in (c), encapsulating heat spreaders in said packages with said solar cell chips, top surfaces of said heat spreaders in contact with bottom surfaces of said solar cell chips, bottom surfaces of said heat spreaders exposed in bottom surfaces of said packages; and
contacting said bottom surfaces of said heat spreaders with cooling devices.

7. The method of claim 1, further including:
before (a), reclaiming and processing scrap wafers from an integrated circuit chip fabrication facility to form said solar cell wafers; and
wherein (a) includes processing said solar cell wafers on at least one tool used to fabricate integrated circuit chips in said integrated circuit chip fabrication facility.

8. The method of claim 1, wherein each of said one or more solar cell chips includes:
a P-doped layer and an N-doped layer in a silicon substrate, said P-doped layer adjacent to a top surface of said substrate and said N-doped layer adjacent to a bottom surface of said substrate;
a dielectric top passivation layer on said top surface of said substrate and a dielectric bottom passivation layer on said top surface of said substrate;
an antireflective coating on said top passivation layer;
a first set of openings through said antireflective coating and through said top passivation layer to said P-doped layer and photolithographically forming a second set of openings through said bottom passivation layer to said N-doped layer;
first metal silicide contacts to said P-doped layer and second metal silicide contacts to said N-doped layer in said first and second openings respectively; and
metal contact frames on said first metal silicide contacts and metal bus bars on said second metal silicide contacts;

9. The method of claim 8, wherein each of said one or more solar cell chips further includes emitter regions in said substrate, said emitter regions extending from said bottom surface of substrate through said N-doped layer into said substrate a further distance than said N-doped layer extends into said substrate, a concentration of N-dopant of said emitters greater than a N-dopant concentration of said N-doped layer.

10. The method of claim 1, wherein each of said one or more solar cell chips range in surface area from about 25 mm² to about 400 mm².
